(19) United States
(12) Patent Application Publication
(10) Pub. No.: US 2007/0045795 A1
(43) Pub. Date: Mar. 1, 2007

(54) MEMS package and method of forming the same

(76) Inventor: Ronald V. McBean, Chandler, AZ (US)

Correspondence Address: INGRASSIA, FISHER & LORENZ, P.C., 7150 E. CAMELBACK ROAD, SUITE 325, SCOTTSDALE, AZ, 85251, US

(21) Appl. No.: 11/217,576

(22) Filed: Aug. 31, 2005

(51) Int. Cl. H01L 23/02

(52) U.S. Cl. 257/678

(57) ABSTRACT

A MEMS package (100, 300) and method of fabrication include a package (100, 300) that is formed by bonding a first component (102, 302), which includes a MEMS device (106, 306) and a substrate (104, 304) upon which the MEMS device (106, 306) was formed as a part thereof, to a second component (202, 402) during wafer level packaging. The first component (102, 302) is bonded to the second component (202, 402) using bump bonding or coined wire bonding. The MEMS device (106, 306) resides in a sealed cavity (250, 350) defined by a collar structure (252, 352) formed by the two components (101, 202, 302, 402). The collar structure (252, 352) provides a sealed airspace in which the MEMS device (106, 306) resides and operates.

### FIELD OF THE INVENTION

The present invention generally relates to semiconductor packaging and methods for fabricating semiconductor packages, and more particularly to wafer level packaging methods for microelectromechanical system (MEMS) devices.

### BACKGROUND OF THE INVENTION

MEMS packaging continues to represent the largest and most prohibitive cost associated with large scale adoption of MEMS devices. Typical MEMS packaging involves cavity-type packaging of the singulated MEMS die. The cavity-type packaging provides an isolated environment for the operation of a MEMS die. Many conventional MEMS packages use a pre-formed package having a cavity into which the MEMS die (post singulation) is placed and bonded. A lid is then placed on top to seal the cavity. However, this pre-formed cavity-type packaging in which three components are required to form the package (the die, the cavity structure and the lid) is expensive because the actual package lid attachment requires precise processing to prevent contamination of the enclosed MEMS die.

In other instances a coating material is formed over the MEMS die (post singulation) whereby the coating material forms an air cavity over the MEMS die upon curing. These types of cavity packages are also relatively expensive and performed at the single device level. Thus it is desirable to reduce the cost of manufacturing MEMS device package.

It is desirable features and characteristics of the present invention will become apparent from the subsequent detailed description of the invention and the appended claims, taken in conjunction with the accompanying drawings and this background of the invention.

### BRIEF DESCRIPTION OF THE DRAWINGS

The present invention will hereinafter be described in conjunction with the following drawing figures, wherein like numerals denote like elements, and wherein

FIG. 1 is a cross-sectional view of a first embodiment of a MEMS package that may be manufactured utilizing an exemplary process in accordance with the present invention;

FIGS. 2-21 are cross-sectional views illustrating various exemplary methodological steps that may be used to manufacture the package shown in FIG. 1;

FIG. 22 is a cross-sectional view of a second embodiment of a MEMS package that may be manufactured utilizing an alternate exemplary process in accordance with the present invention; and

FIG. 23-30 are cross-sectional views illustrating various exemplary methodological steps that may be used to manufacture the package shown in FIG. 22.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention. Provided is a MEMS device package and a method of fabricating the MEMS device package that incorporates the substrate upon which the MEMS device is formed as a defining part of the package thus requiring fewer manufacturing step to form the package. The package is formed at the wafer level prior to singulation of the MEMS device wafer into individual MEMS die.

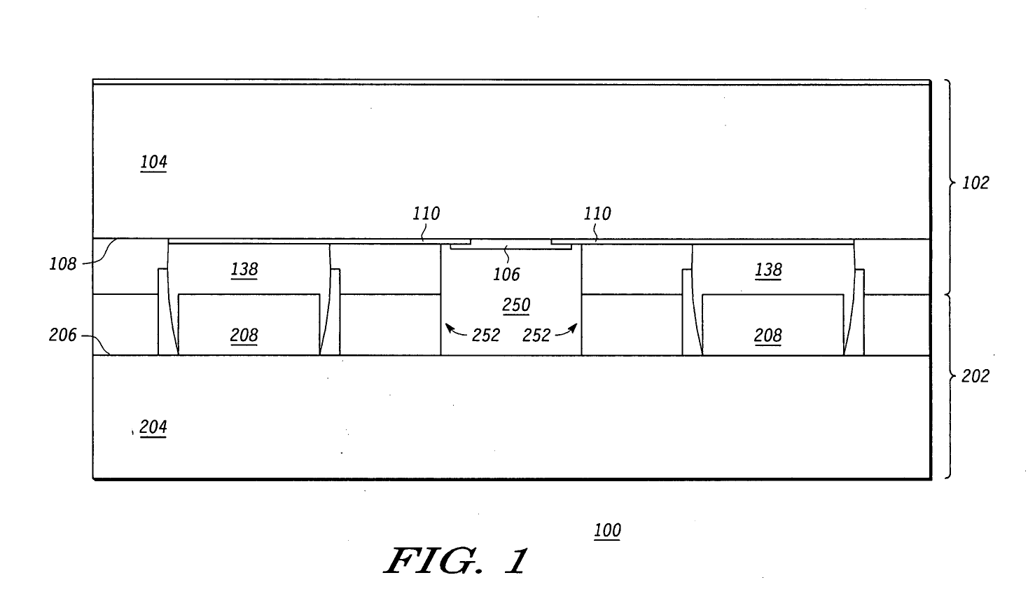

FIG. 1 is a cross-sectional view of a MEMS package 100 that may be manufactured according to an exemplary process of the present invention. MEMS package 100 is formed by bonding a first component 102 and a second component 202 that when coupled to said first component 102 forms a cavity 250 within which a MEMS device 106 resides. First component 102 includes a substrate 104 having MEMS device 106, e.g. a switch, an accelerometer, an acoustic filter, a sensor, or an optical MEMS component, formed on a first surface 108 thereof according to well know practices. First component 102 further includes circuitry 110 for electrically communicating with MEMS device 106. It should be appreciated that first component 102 includes the actual substrate 104 on which MEMS device 106 was formed.

Second component 202 typically includes an organic substrate 204 having a plurality of non-solder masks defined I/O pads 208 on a first surface 206. MEMS package 100 further includes a collar structure 252 that partially defines a sealed cavity 250 in which MEMS device 106 is positioned. Collar structure 252 protects MEMS device 106 during the solder bump attachment process. Collar structure 252 is formed when a first passivation structure (described below) on first component 102 is bonded to a second passivation structure (described below) on second component 202.

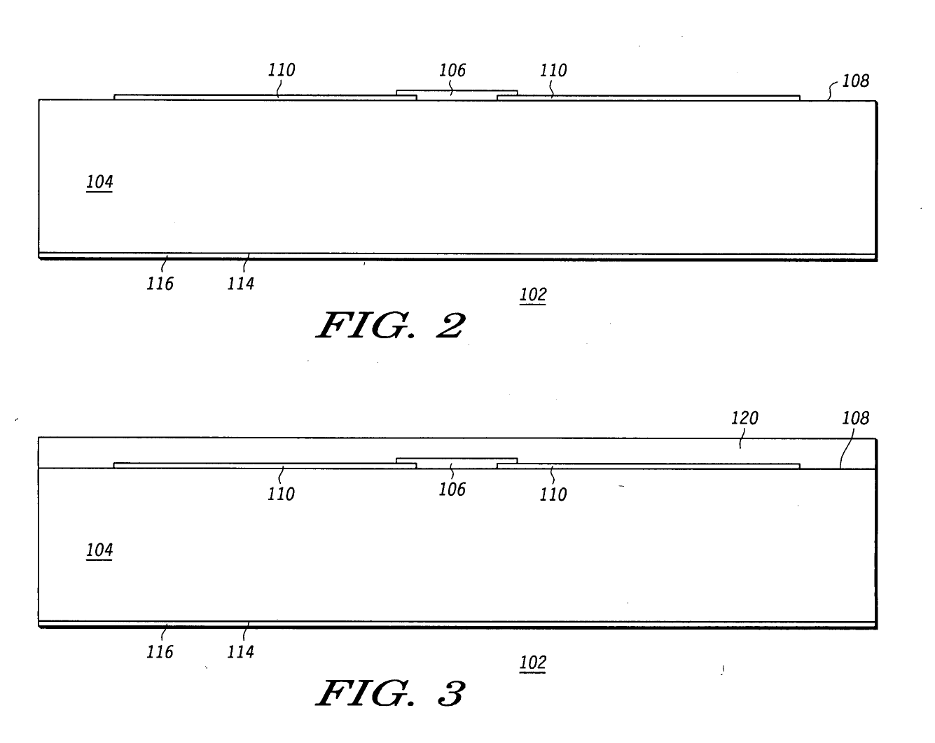

FIGS. 2-21 are cross-sectional views illustrating a preferred process for manufacturing package 100. For purposes of explanation, the process of forming first component 102 will be described first, although it should be understood that alternatively second component 202 could be fabricated prior to, or simultaneously with, the fabrication of first component 102.

Referring to FIG. 2, a standard MEMS device 106 is formed on a substrate 104 in accordance with well known practices. Substrate 104 is a standard semiconductor substrate and may be formed of gallium arsenide (GaAs), silicon germanium (SiGe), or silicon (Si). MEMS device 106 is formed on first surface 108 of substrate 104. In addition, metallized circuitry 110, e.g. copper or aluminum that may be gold plated, including MEMS device I/O pads 118, is formed on first surface 108 of substrate 104. A gold backing 116 for electrical interconnect of MEMS device 106 may be formed on a second surface 114 of substrate 104 if desired. Likewise, a layer of glass may be formed over first surface 108 and circuitry 110 of substrate 104 for passivation.

Referring to FIG. 3 a first passivation layer 120 is deposited on first component 102. In this particular embodiment, first passivation layer 120 is a polymer benzocyclobutene (BCB) coating that may be deposited by spin coating. Alternatively, first passivation layer 120 may be any photo-imageable dielectric material, e.g. a polyimide material. Layer 120 is baked at a temperature in a range of approximate 110° C. to 120° C. for a period in a range of approximately 85 to 95 seconds to stabilize the material.

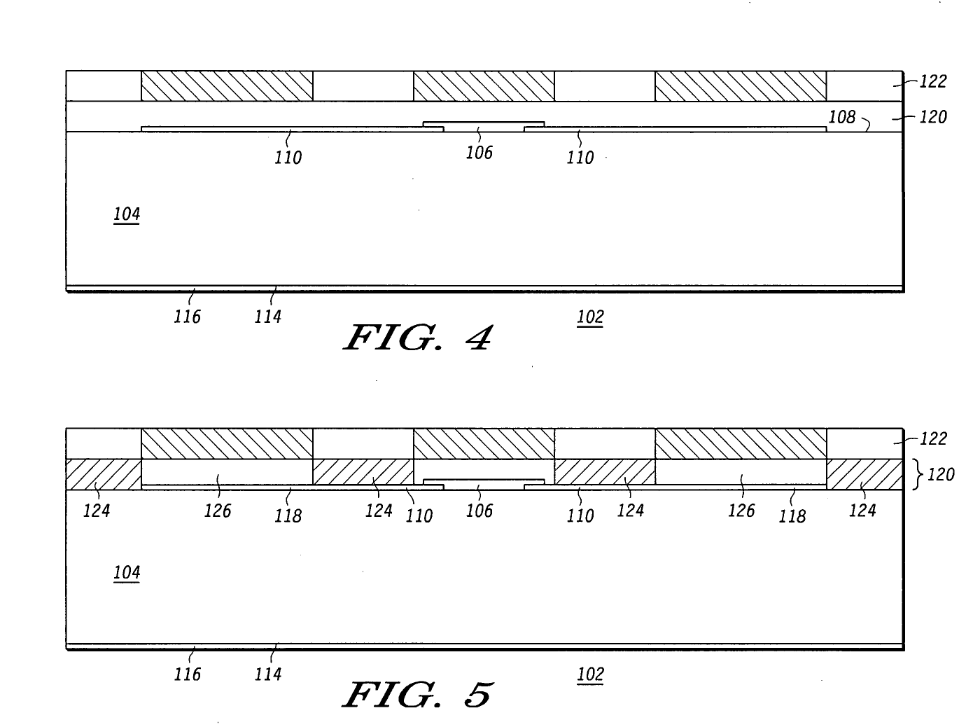

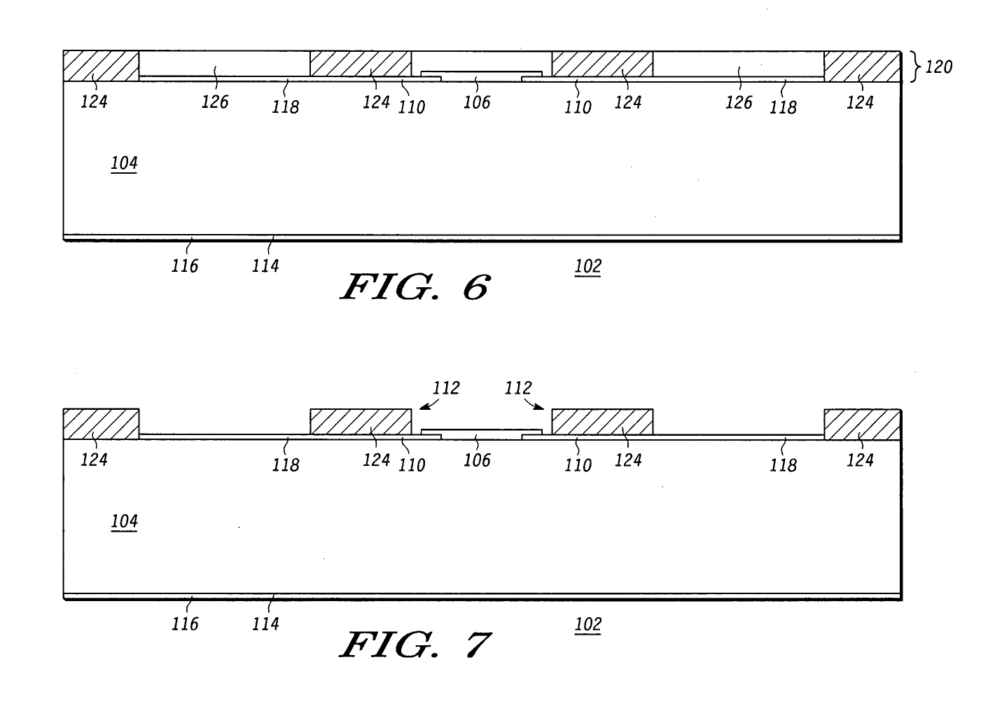

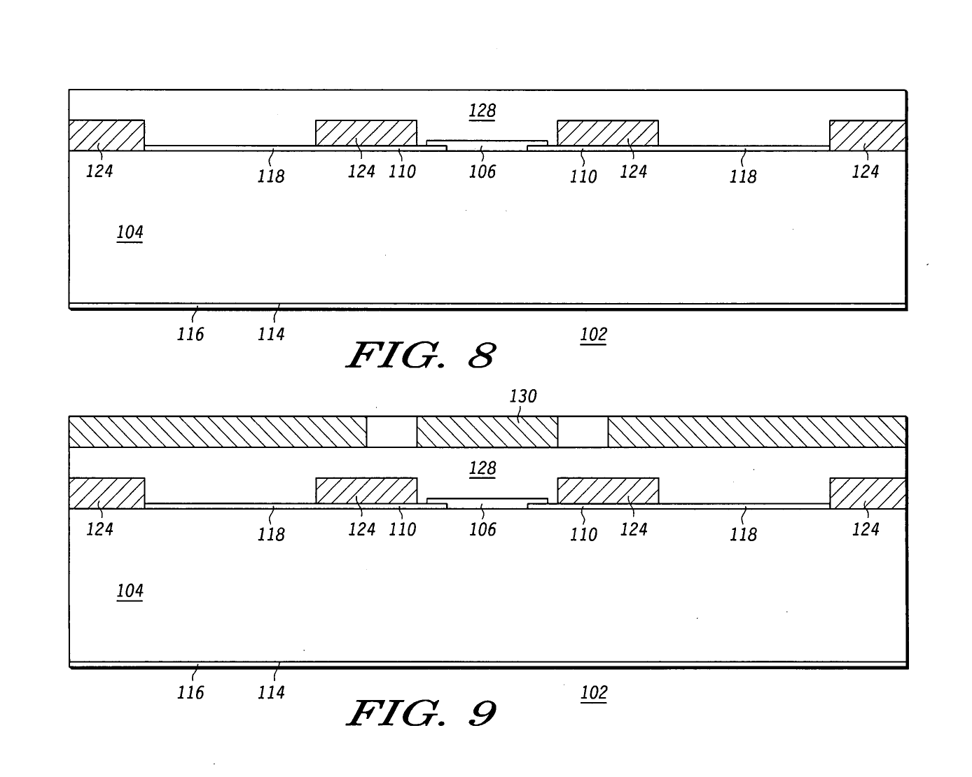

Referring to FIG. 4, after layer 120 is stabilized, a negative image photomask 122 is aligned and positioned on a surface of layer 120 using well known photolithographic techniques including patterning photo mask 122 to create a negative image. First component 102 is exposed, and photomask 122 is removed leaving a plurality of exposed portions 124 and a plurality of unexposed portions 126 as shown in FIGS. 5 and 6. First component 102 is next placed in a developer solution, such as Dow® DS2100 or DS3000, to rinse away the unexposed portions 126 resulting in first component 102 as shown in FIG. 7. An optional final rinse in deionized (DI) water removes any remaining developer solution. First component 102 is next baked at a temperature in a range of approximately 230° C. to 240° C. for a period of approximately 60 to 90 minutes to cure the exposed portions 124, forming a portion of a first passivation structure 112.

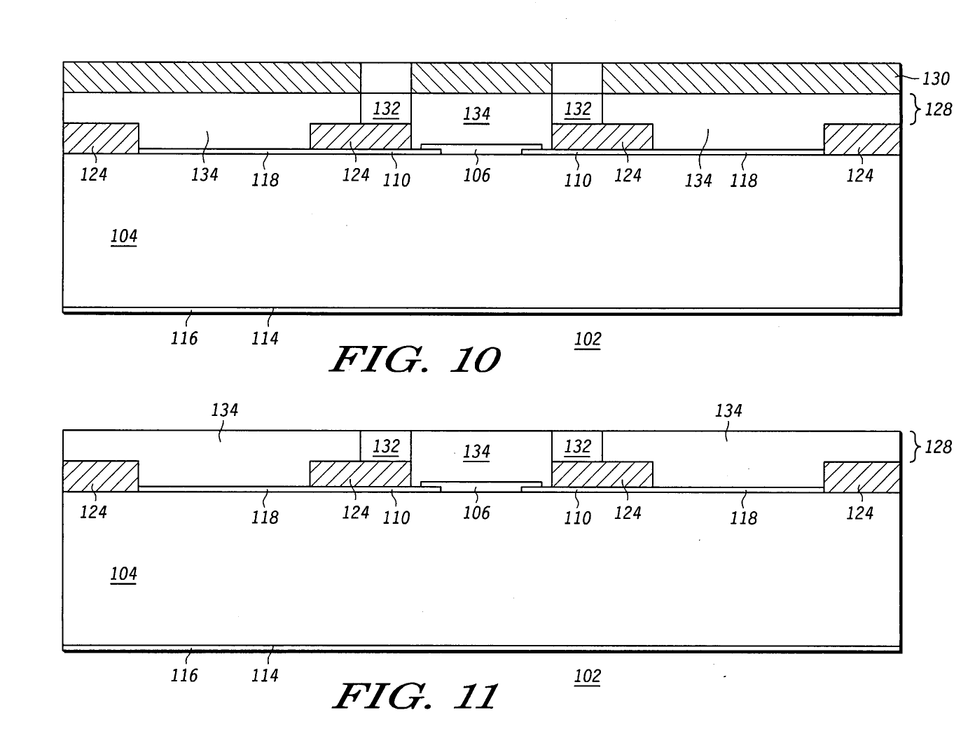

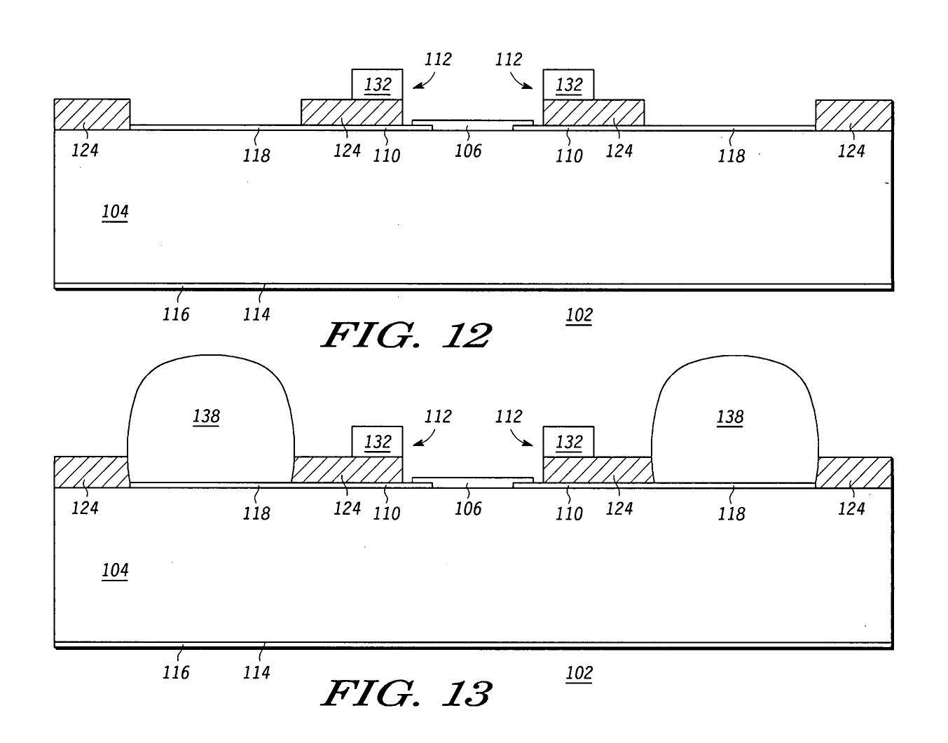

FIG. 8 illustrates a second passivation layer 128, such as a polymer BCB coating, deposited on first component 102. Second passivation layer 128 may be deposited by spin-coating as was layer 120. Layer 128 is then baked to stabilize the material. After layer 128 is stabilized, a second negative image photomask 130 is aligned and positioned as shown in FIG. 9 in accordance with well known photolithography techniques. Subsequent to the positioning and alignment of photomask 130, first component 102 is exposed to form a plurality of exposed portions 132 and a plurality of unexposed portions 134 as illustrated in FIG. 10. Subsequent removal of photomask 130 leaves a plurality of exposed portions 132 and unexposed portions 134 as shown in FIG. 11. First component 102 is subsequently placed in a developer solution, such as Dow® DS2100 or DS3000, to remove unexposed portions 134 as is shown in FIG. 12. An optional final rinse in DI water removes any remaining developer solution. First component 102 is next baked at a temperature in a range of 230° C. to 240° C. for a period of approximately 60 to 90 minutes to cure the plurality of exposed portions 132 and further define first passivation structure 112. As best seen in FIG. 12, the plurality of exposed portions 124 in combination with the plurality of exposed portions 132 that are formed around the MEMS device 106 form a stepped passivation structure that prevents contaminants from damaging MEMS device 106 during subsequent processing steps.

First component 102, and more particularly the MEMS device metallized circuitry 110, including the I/O pads 118, are next cleaned to remove any residual polymer material. After cleaning is complete, first component 102 is bumped by solder jet printing as illustrated in FIG. 13 to prepare for bonding first component 102 to second component 202. It should be appreciated that first component 102 may in the alternative be bumped by stencil printing or electro-plating. During the process of solder jet printing, a plurality of solder balls 138 are formed to a size of approximately 60 microns by depositing a solder material, such as tin/lead, tin/antimony, or tin/gold, onto the I/O pads 118

Subsequent to solder jet printing, MEMS device 106 is released (e.g. made functional) by etching away a sacrificial, protective layer of silicon dioxide or silicate glass (not shown) that surrounds MEMS device 106. A typical wet release procedure includes an acid etch in a mixture of hydrofluoric and acetic acid, followed by rinsing and drying. Alternatively, dry plasma etching with chemically active ions, such as oxygen, chlorine, or fluorine ions, can be used. In this embodiment, a DI water rinse removes any residual acid followed by a rinse in isopropyl alcohol. Subsequent to the release of MEMS device 106, MEMS device 106 is active, and the solder ball preparation of first component 102 is complete as shown in FIG. 13.

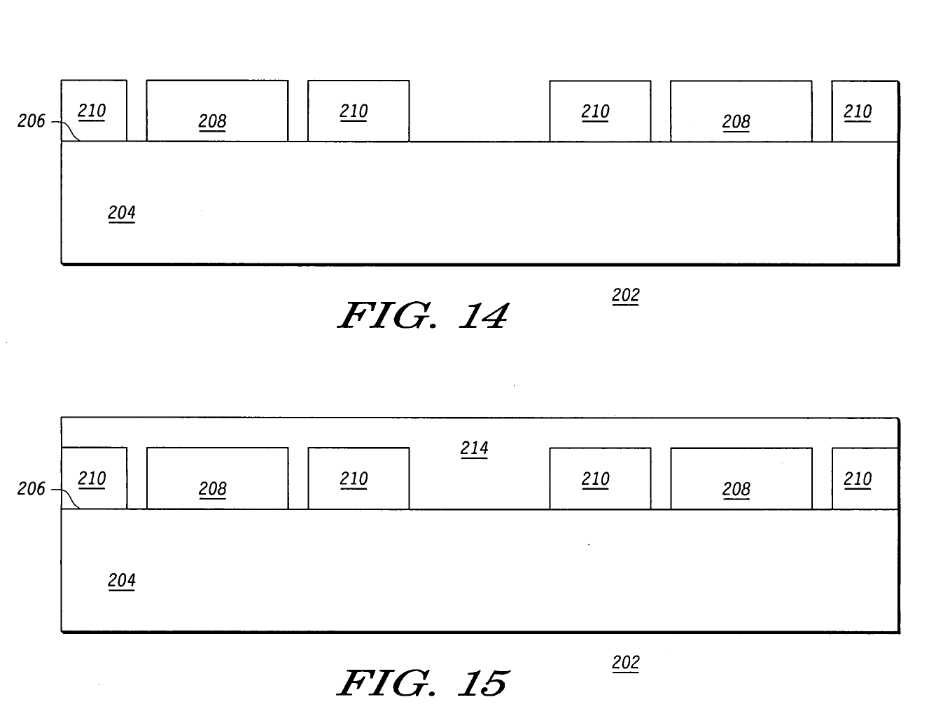

As was previously noted, the above-described MEMS package 100 is fabricated by bonding two separate component parts; first component 102, which includes MEMS device 106 and substrate 104 on which MEMS device 106 was fabricated, and second component 202. Referring to FIG. 14, the manufacture of second component 202 in accordance with an embodiment of the invention begins with providing an organic substrate 204, such as an FR4 or FR5 laminate constructed from glass fabric and impregnated with epoxy resin and copper foil. Alternatively, second component 202 may be made of a non-organic substrate such as alumina, or low temperature co-fired ceramic (LTCC). A plurality of solder masks 210 and I/O pads 208 are formed on surface 206 and are defined by non-solder mask processing, such as by typical I/O pad metallurgy.

After I/O pads 208 are formed, a passivation layer 214 is deposited on second component 202. In this particular embodiment, passivation layer 214 is a polymer BCB coating that is deposited, such as by spin coating, on surface 206 of substrate 204 as illustrated in FIG. 15. Alternatively, passivation layer 214 may be any photo-imageable dielectric material, e.g. a polyimide material. Layer 214 is baked at a temperature in a range of approximately 110° C. to 120° C. for a period of approximately 85 to 95 seconds to stabilize coating 214.

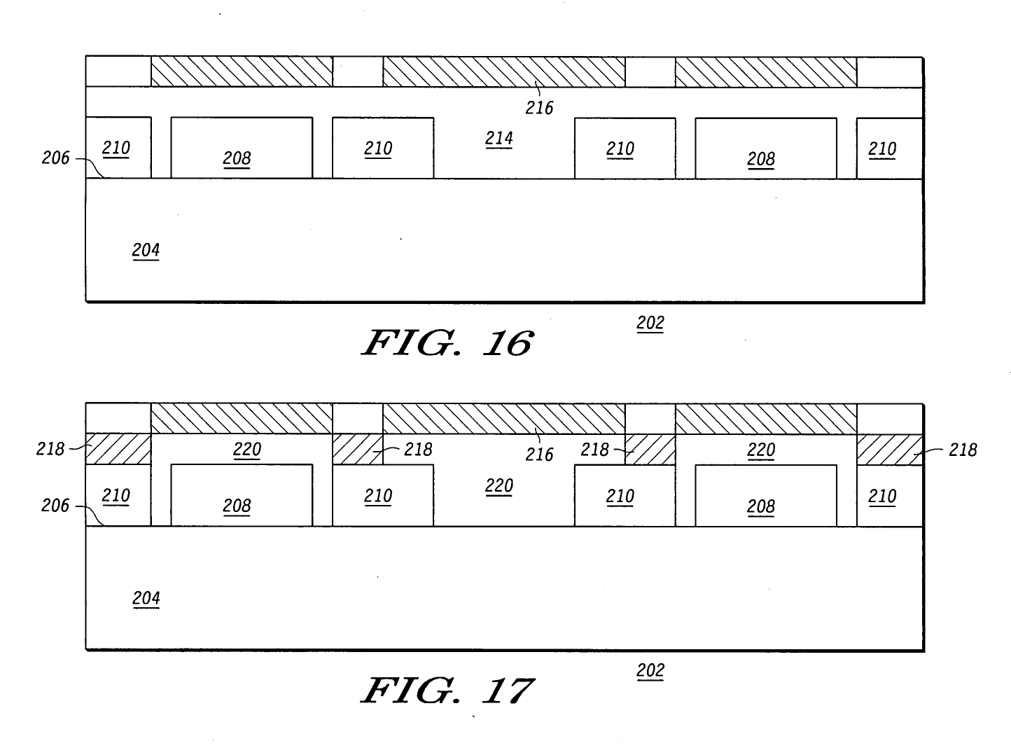

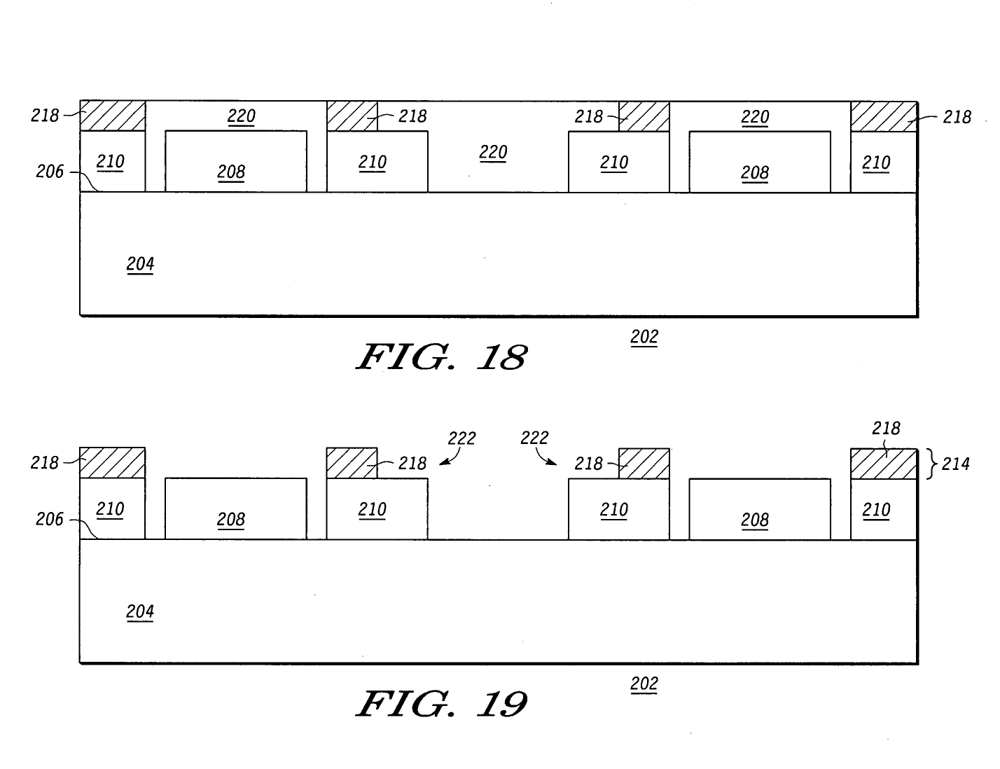

Referring now to FIG. 16, a negative image photomask 216 is aligned and positioned on a surface of coating 214 in accordance with standard photolithography techniques, including patterning photomask 216 as illustrated to create a negative image and allow for exposure of portions of layer 214. Next, second component 202 is exposed as illustrated in FIG. 17 to form exposed portions 218 and unexposed portions 220 of layer 214 after which the photomask 216 is removed as shown in FIG. 18. Second component 202 is subsequently placed in a developer solution, such as Down® DS2100 or DS3000, to rinse away unexposed portions 220, resulting in second component 202 as shown in FIG. 19 with exposed portions 218 remaining to define a second passivation structure 222. An optional final rinse in DI water removes any remaining developer solution. Exposed portions 218 do not undergo a second heating step to cure the exposed portions 218 at this point in the fabrication process. The completed second component 202 is shown in FIG. 19.

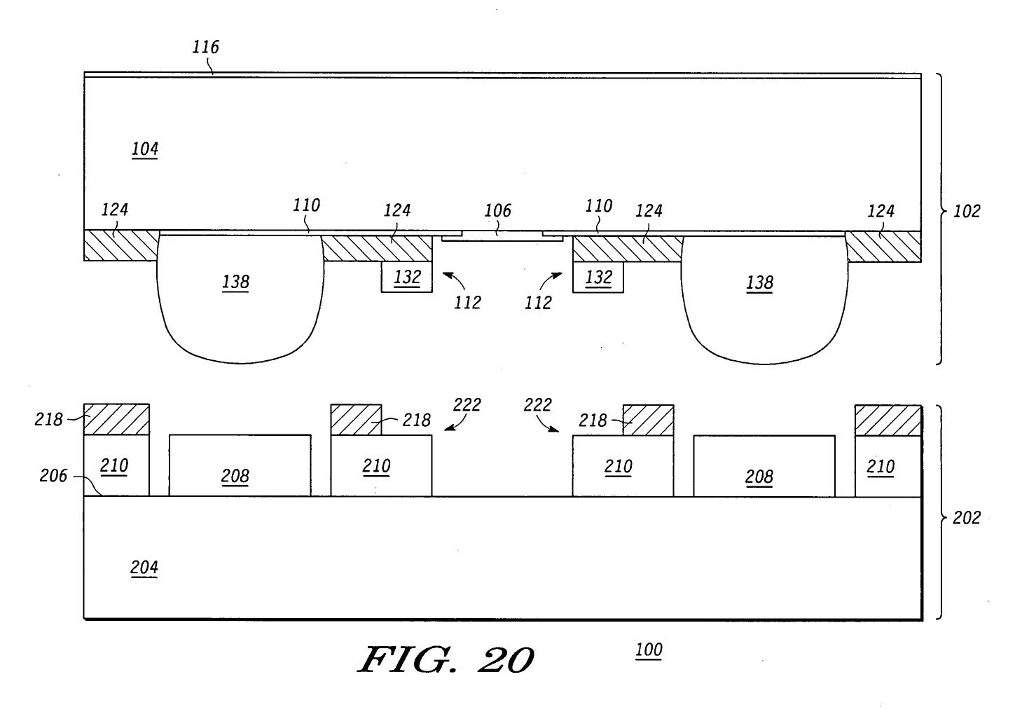

After first component 102 and second component 202 have been fabricated as previously described, the two components are bonded together to form MEMS package 100 as described with regard to FIG. 1. Referring to FIG. 20, wafer substrate 102 and second component 202 are aligned and undergo a solder bump reflow process. More specifically, solder bumps 138 of first component 102 are aligned with I/O pads 208 of second component 202.

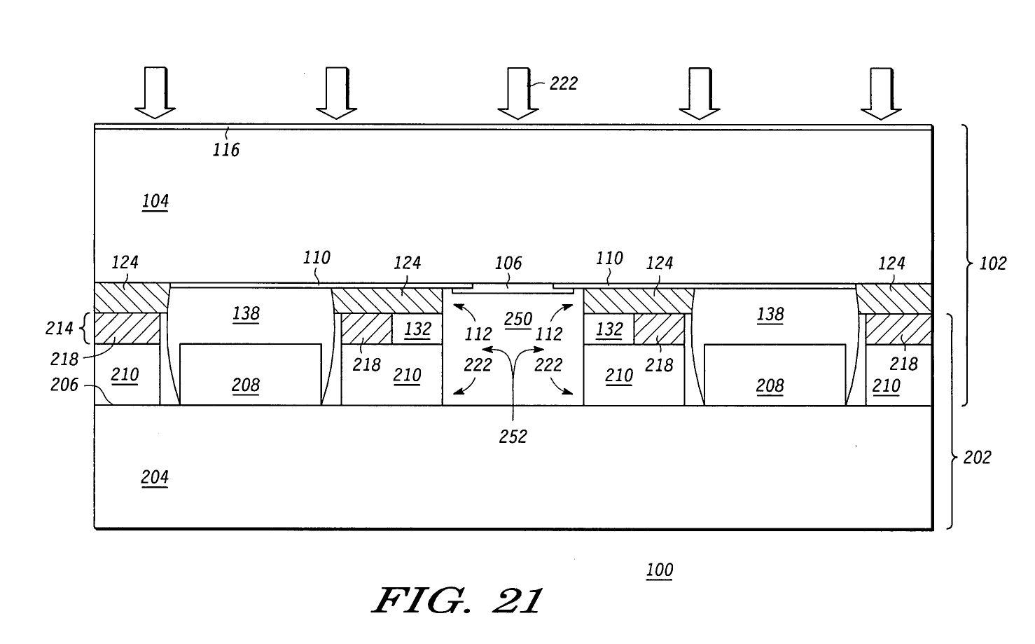

A clamping pressure, as indicated by arrows 224 in FIG. 21, is applied during the reflow process while first component 102 and second component 202 are heated at a temperature in a range of approximately 250° C. to 260° C. for a period of approximately 2-4 minutes. Next, MEMS package 100 is heated at a temperature in a range of approximately 230° C. to 240° C. for a period of approximately 60-90 minutes to promote curing of exposed portions 218. This curing step promotes adhesive bonding between exposed portions 218 of second passivation structure 222 and the plurality of exposed portions 124 and 132 of first passivation structure 112. The bonding of first passivation structure 112 and second passivation structure 222 forms collar structure 252 that partially defines sealed cavity 250 in which MEMS device 106 is positioned. The completed MEMS package 100 is shown in FIG. 1.

It should be appreciated that alternatively first passivation structure 112 and second passivation structure 222 may both be fabricated on the same component, either the first component or second component, prior to the bonding together of the first component and the second component. A final heating step would cure an exposed portion of the combined passivation structure and result in bonding of the two components.

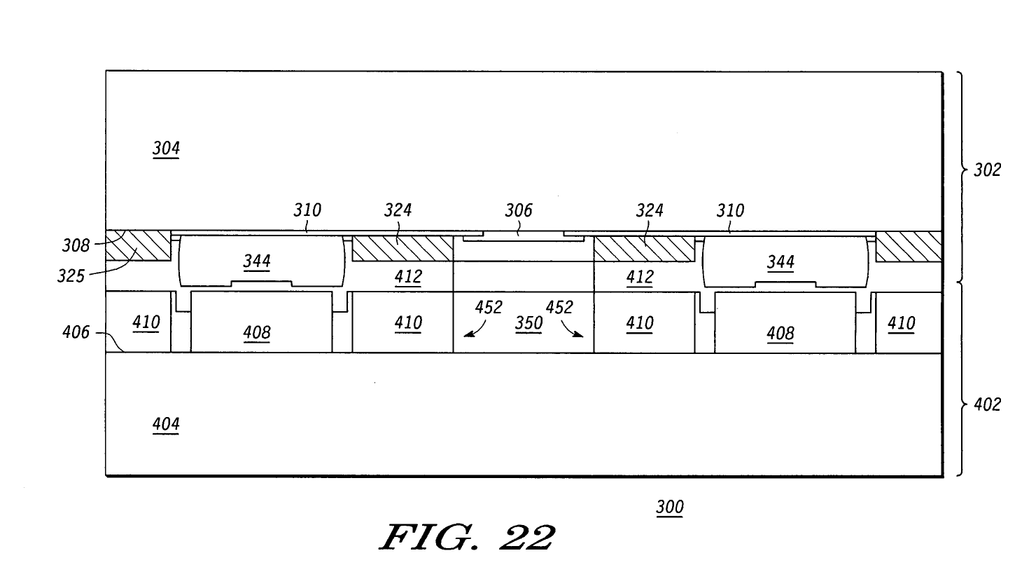

FIG. 22 is a cross sectional view of a MEMS package 300 that may be manufactured in accordance with a second exemplary process of the present invention. MEMS package 300 is formed in generally the same manner as MEMS package 100 as described in connection with FIGS. 1-21 by bonding a first component 302, that includes a substrate 304 upon which a MEMS device 306 is formed, to a second component 402. Substrate 304 further includes circuitry 310 on first surface 308, in electrical communication with MEMS device 306.

Second component 402 is typically formed of an organic substrate 404 having a plurality of non-solder mask defined I/O pads 408 formed on a surface 406. Alternatively, second component 402 may be formed of a non-organic substrate such as alumina or low temperature co-fired ceramic (LTCC). A plurality of solder masks 410 are also formed on surface 406 to provide protection to MEMS device 306 during the attachment process. First component 302 and second component 402 are bonded together using a coined wirebond attachment process, and more particularly, a flip chip coined wirebond bump technique, in which a plurality of coined gold bumps 344 are formed to bond the two components. MEMS package 300 includes a collar structure 452 defined by a plurality of exposed portions 324 of a passivation layer (described below), an anisotropic conductive film (ACF) (described below), and a plurality of solder masks 410. A sealed cavity 350 defined by collar structure 452 provides a sealed airspace in which MEMS device 306 operates.

The process begins with the formation of first component 302 or second component 402. While the process of forming first component 302 will be described first, it should be understood that second component 402 could be fabricated prior to, or simultaneously with, the fabrication of first component 302.

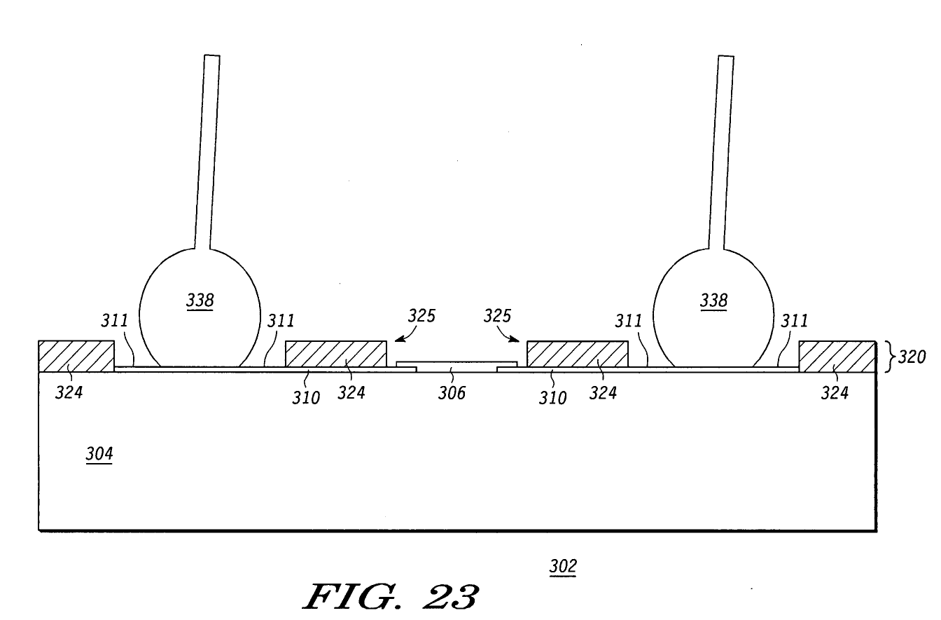

First component 302 is fabricated using a multi-step process, and begins by providing a standard MEMS device 306 formed on a substrate 304 according to well known practices, as illustrated in FIG. 23. First component 302 is formed in generally the same manner as first component 102 (FIGS. 1-7), including the formation of a plurality of exposed portions 324 of a passivation layer 320, such as a polymer BCB coating, to form a passivation structure 325. It should be appreciated that first component 302 includes the substrate 304 upon which MEMS device 306 was formed.

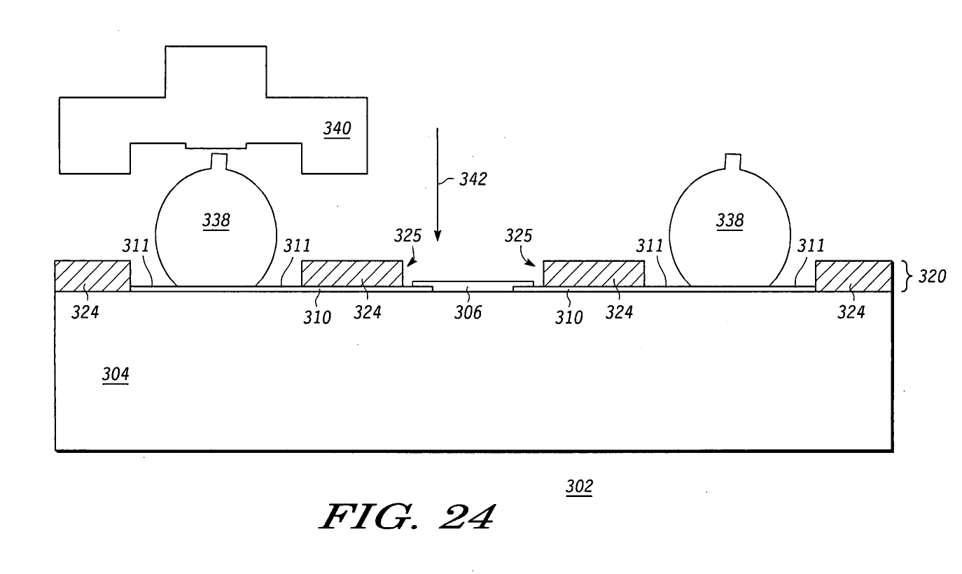

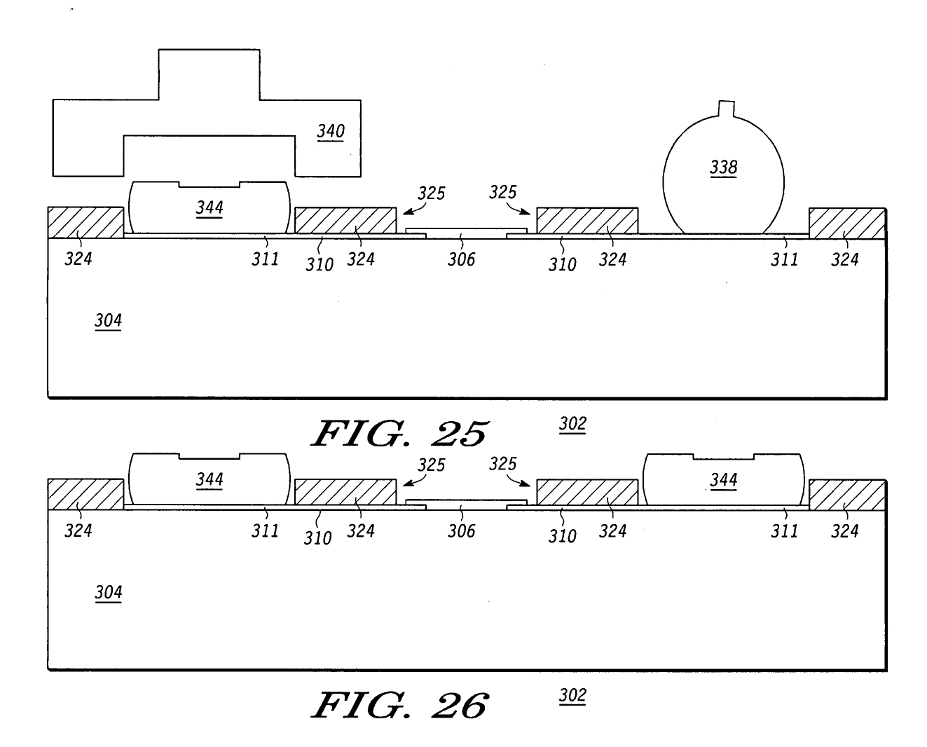

Thereafter, first component 302, and more particularly the MEMS device metal circuitry 310, including a plurality of in-out (I/O) pads 311, is cleaned to remove any residual layer 320. A plurality of wire bonds 338 are subsequently attached to metal circuitry 310 and more particularly to the I/O pads 311. Wire bonds 338 are initially formed according to standard wire bonding procedures in which a gold 1.0 millimeter wire is coupled to the metal circuitry 310, and more specifically bonded to MEMS I/O pads 311. After wire bonds 338 are coupled to I/O pads 311, they are clipped as illustrated in FIG. 24 prior to a coining process. A single site coining tool 340 is used to form a plurality of gold bumps 344. More particularly, coining tool 340 is applied to wire bonds 338 in a downward motion as indicated by arrow 342. This downward motion deforms wire bonds 338 to form gold bumps 344 as shown in FIG. 25. This process is repeated for each wire bond 338 until a plurality of gold bumps 344 have been formed as illustrated in FIG. 26. Alternatively, coining of wire bonds 338 can be done in parallel using a wafer level tool that coins multiple wire bond sites simultaneously.

As was the case previously, MEMS device 306 is released by etching away a sacrificial, protective layer of silicon dioxide or silicate glass (not shown) that surrounds the MEMS device 306 with a wet release procedure, and more specifically an acid etch in a mixture of hydrofluoric and acetic acid. A DI water rinse removes any residual acid followed by a rinse in isopropyl alcohol. Subsequent to the release of MEMS device 306, MEMS device 306 is active, and the coined wirebond preparation of first component 302 is complete as shown in FIG. 26.

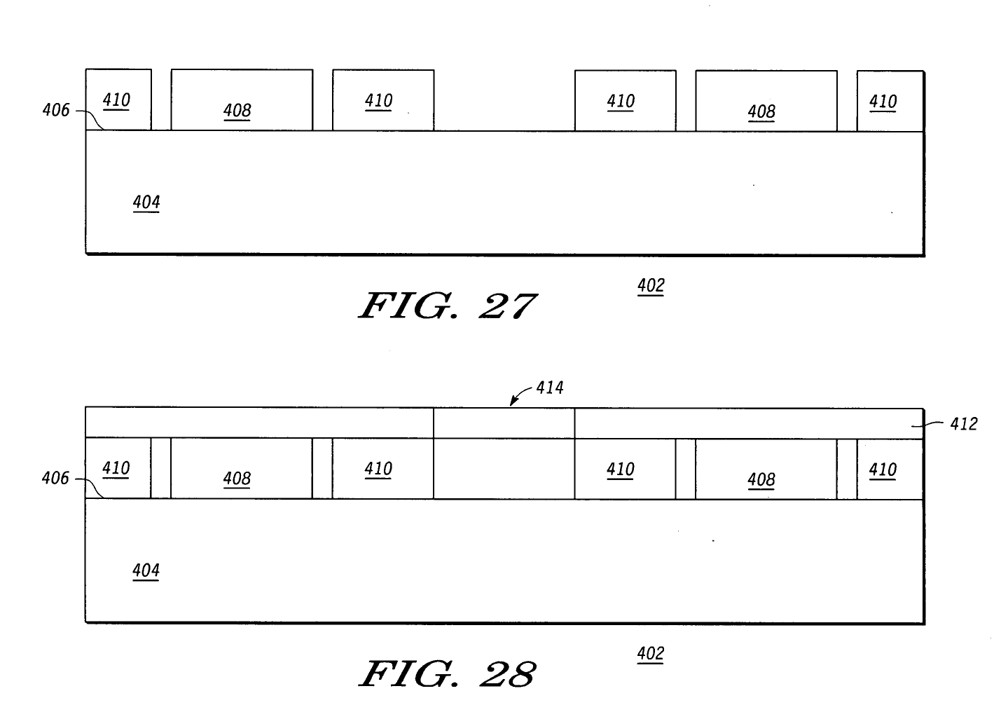

MEMS package 300 is fabricated by bonding together two separate component parts, first component 302, including substrate 304 upon which MEMS device 306 was fabricated, and second component 402. Referring to FIG. 27, substrate 404, such as an FR4 or FR5 laminate constructed from glass fabric and impregnated with epoxy resin and copper foil, is provided. The plurality of solder mask 410 and I/O pads 408 defined by non-solder mask processing, such as by typical I/O pad metallurgy, are formed on first surface 406 of substrate 404.

After non-solder mask defined I/O pads 408 are formed, an uncured, die-cut anisotropic conductive film (ACF) 412 is aligned and positioned on second component 402, and more particularly on I/O pads 408 and solder masks 410 as illustrated in FIG. 28. Film 412 has adhesive properties that promote subsequent bonding of first component 302 and second component 402. An opening 414 is die-cut into film 412 to aid in defining the sealed cavity or airspace. The completed second component 402 is shown in FIG. 28.

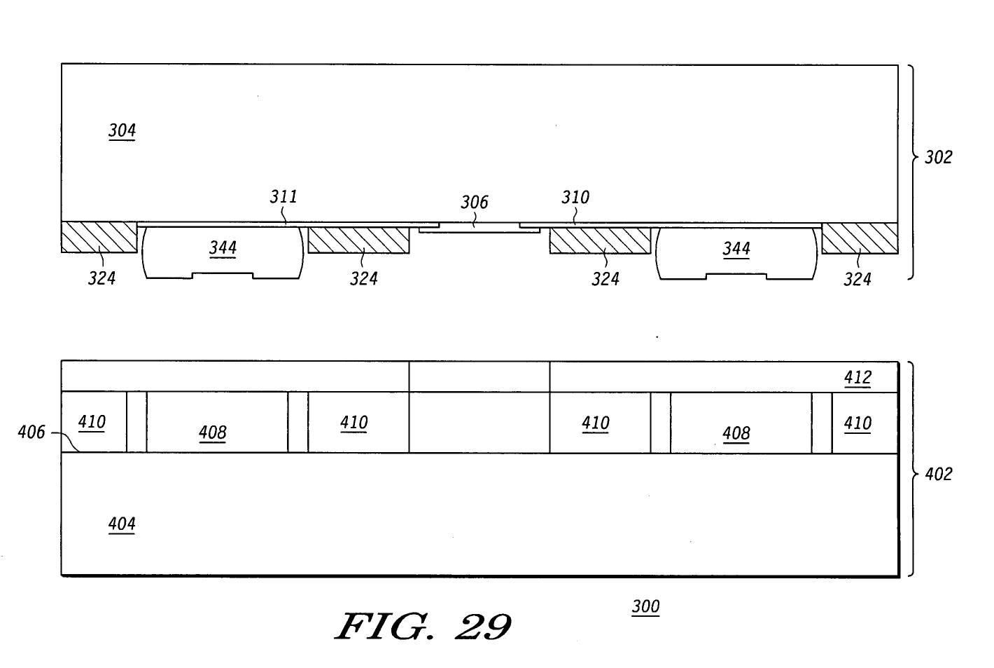

First component 302 and second component 402 are fabricated as previously described and bonded together to form MEMS package 300 (shown in FIG. 29). In particular, gold bumps 344 of first component 302 are aligned with I/O pads 408 of second component 402 and the two components are bonded during a thermo-bonding step.

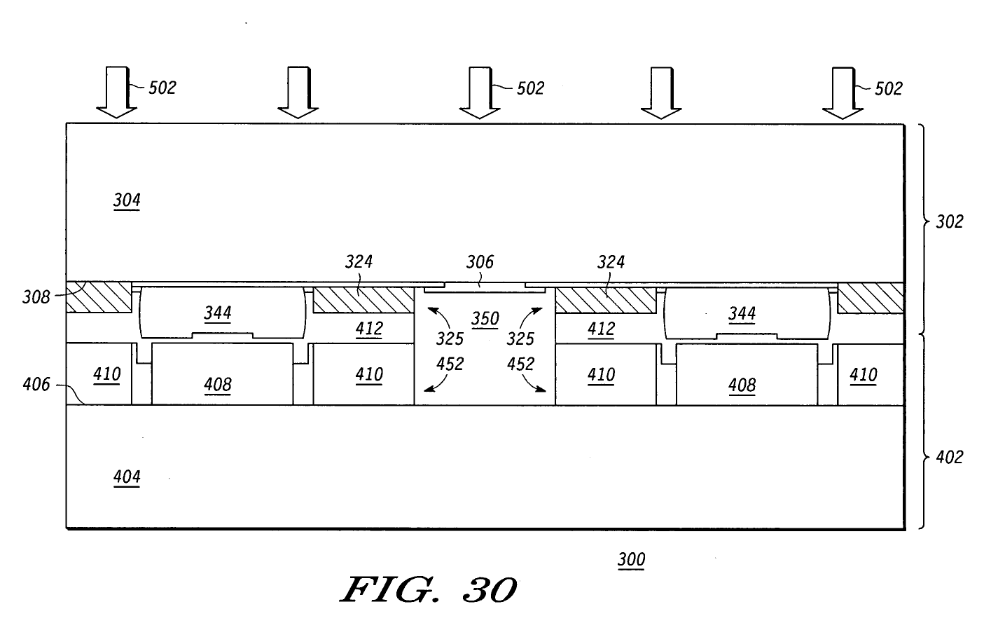

A clamping pressure, as indicated by arrows 502 in FIG. 30, is applied during the thermobonding process during which first component 302 and second component 402 are heated at a temperature in a range of approximately 180° C. to 190° C. for a period of approximately 60 to 70 minutes. This thermobonding step acts as a cure for ACF 412 and provides adhesion between gold bumps 344 and I/O pads 408 and passivation structure 325 and solder masks 410. The bonding of passivation structure 325, ACF 412, and solder masks 410 forms collar structure 452 that partially defines sealed cavity 350 in which MEMS device 306 is positioned. The completed MEMS package 300 is shown in FIG. 22.

Accordingly, provided is a microelectromechanical system (MEMS) package comprising: a first component including a substrate; a MEMS device attached to the substrate; and a second component coupled to and spaced from said first component to form a cavity between the first and second components, wherein the MEMS device resides. The cavity may be partially defined by a collar structure comprised of a first passivation structure bonded to a second passivation structure. The first and second passivation structures may comprise benxocyclobutene (BCB). The collar structure may comprise a solder mask bonded to a passivation structure having an anisotropic conductive film (ACF) there between. The MEMS device may be one of a switch, an accelerometer, an acoustic filter, a sensor, or an optical MEMS component.

In addition, provided is a microelectromechanical system (MEMS) package comprising: a first component including a substrate having a MEMS device attached to the substrate; and a second component coupled to and spaced from the first component forms a cavity within which the MEMS device resides, wherein the cavity is partially defined by a collar structure formed about the MEMS device. The collar structure may comprise a first passivation structure bonded to a second passivation structure. The first and second passivation structures may comprise benxocyclobutene (BCB). The collar structure comprises a solder mask bonded to a passivation structure having an anisotropic conductive film (ACF) there between

Finally, provided is a method of fabricating a microelectromechanical system (MEMS) package, the method comprising: providing a first component including a substrate; forming a MEMS device on the substrate; providing a second component over the MEMS device that when coupled to said first component forms a cavity within which the MEMS device resides. The first component may be flip chip bonded to the second component. The first component may be coupled to the second component by solder bump bonding. The first component may be coupled to the second component by coined wire bonding. The cavity may be defined by forming a collar structure about the MEMS device. The step of forming the collar structure may include forming the collar structure on the first component prior to coupling the first component to the second component. The step of forming the collar structure may include forming the collar structure on the second component prior to coupling the first component to the second component. The step of forming the collar structure may include forming a portion of the collar structure on the first component and a portion of the collar structure on the second component prior to coupling the first component to the second component. The step of forming the collar structure may include bonding a first passivation structure and a second passivation structure. The step of forming the collar structure may include bonding a passivation structure and a solder mask having an anisotropic conductive film (ACF) there between.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

What is claimed is:

1. A microelectromechanical system (MEMS) package comprising:
a first component including a substrate;
a MEMS device attached to the substrate; and
a second component coupled to and spaced from said first component to form a cavity between the first and second components, wherein the MEMS device resides.

2. The package of claim 1, wherein the cavity is partially defined by a collar structure.

3. The package of claim 2, wherein the collar structure comprises a first passivation structure bonded to a second passivation structure.

4. The package of claim 3, wherein the first and second passivation structures comprise benxocyclobutene (BCB).

5. The package of claim 2, wherein the collar structure comprises a solder mask bonded to a passivation structure having an anisotropic conductive film (ACF) there between.

6. The package of claim 1, wherein the MEMS device is one of a switch, an accelerometer, an acoustic filter, a sensor, or an optical MEMS component.

7. A microelectromechanical system (MEMS) package comprising:
a first component including a substrate having a MEMS device attached to the substrate; and
a second component coupled to and spaced from the first component forms a cavity within which the MEMS device resides, wherein the cavity is partially defined by a collar structure formed about the MEMS device.

8. The package of claim 7, wherein the collar structure comprises a first passivation structure bonded to a second passivation structure.

9. The package of claim 8, wherein the first and second passivation structures comprise benxocyclobutene (BCB).

10. The package of claim 7, wherein the collar structure comprises a solder mask bonded to a passivation structure having an anisotropic conductive film (ACF) there between

11. A method of fabricating a microelectromechanical system (MEMS) package, the method comprising:
providing a first component including a substrate;
forming a MEMS device on the substrate;
providing a second component over the MEMS device that when coupled to said first component forms a cavity within which the MEMS device resides.

12. The method of claim 11, wherein the first component is flip chip bonded to the second component.

13. The method of claim 11, wherein the first component is coupled to the second component by solder bump bonding.

14. The method of claim 11, wherein the first component is coupled to the second component by coined wire bonding.

15. The method of claim 11, wherein the cavity is defined by forming a collar structure about the MEMS device.

16. The method of claim 15, wherein the step of forming the collar structure includes forming the collar structure on the first component prior to coupling the first component to the second component.

17. The method of claim 15, wherein the step of forming the collar structure includes forming the collar structure on the second component prior to coupling the first component to the second component.

18. The method of claim 15, wherein the step of forming the collar structure includes forming a portion of the collar structure on the first component and a portion of the collar structure on the second component prior to coupling the first component to the second component.

19. The method of claim 15, wherein the step of forming the collar structure includes bonding a first passivation structure and a second passivation structure.

20. The method of claim 15, wherein the step of forming the collar structure includes bonding a passivation structure and a solder mask having an anisotropic conductive film (ACF) there between.
